(19) United States
(12) Patent Application Publication
(10) Pub. No.: US 2025/0218659 A1
(43) Pub. Date: Jul. 3, 2025

(54) THIN FILM CAPACITOR AND ELECTRONIC CIRCUIT BOARD HAVING THE SAME

(71) Applicant: TDK Corporation, Tokyo (JP)

(72) Inventors: Yoshiaki HAYAMIZU, Tokyo (JP); Daiki ISHII, Tokyo (JP); Mitsuhiro TOMIKAWA, Tokyo (JP); Kenichi YOSHIDA, Tokyo (JP); Yasunori HARADA, Tokyo (JP)

(21) Appl. No.: 18/841,838

(22) PCT Filed: Dec. 9, 2022
(86) PCT No.: PCT/JP2022/045458

§ 371 Date: Aug. 27, 2024

Related U.S. Application Data
(60) Provisional application No. 63/314,682, filed on Feb. 28, 2022.

(51) Int. Cl. H01G 4/005; H01G 4/33; H05K 1/18

(52) U.S. Cl. CPC H01G 4/005; H01G 4/33; H05K 1/18; H05K 2201/10015

(57) ABSTRACT

To provide a thin film capacitor having a pair of terminal electrodes capable of being disposed on the same plane. A thin film capacitor includes: a metal foil having a non-roughened center portion and a roughened upper surface; a dielectric film covering the roughened upper surface of the metal foil; an electrode layer contacting the metal foil; an electrode layer contacting the dielectric film without contacting the metal foil; and an insulating member positioned between the electrode layers and. The metal foil has a groove formed so as to penetrate a roughened surface layer of the metal foil and exposing therethrough the non-roughened center portion. The insulating member contacts the center portion of the metal foil that is exposed to the bottom of the groove.

### TECHNICAL FIELD

The present disclosure relates to a thin film capacitor and an electronic circuit board having the same.

### BACKGROUND ART

IC-mounted circuit boards are commonly mounted with a decoupling capacitor so as to stabilize the potential of a power supply for an IC. As the decoupling capacitor, a multilayer ceramic chip capacitor is typically used, and a large number of the multilayer ceramic chip capacitors are mounted on the surface of the circuit board to thereby achieve a required decoupling capacitance.

In recent years, a mounting space for a large number of multilayer ceramic chip capacitors may become insufficient due to miniaturization of a circuit board. To cope with this, a thin film capacitor capable of being embedded in a circuit board is sometimes used in place of the multilayer ceramic chip capacitor (see Patent Documents 1 to 4).

A thin film capacitor described in Patent Document 1 uses a porous metal substrate and is structured such that an upper electrode is formed on the surface of the porous metal substrate with a dielectric film interposed therebetween. A thin-film capacitor described in Patent Document 2 uses a metal substrate whose one main surface is roughened and is structured such that an upper electrode is formed on the roughened surface with a dielectric film interposed therebetween. Thin film capacitors described in Patent Documents 3 and 4 are structured such that a conductive porous substrate is formed as a support, and an upper electrode is formed on a roughened surface of the substrate with a dielectric film interposed therebetween.

### CITATION LIST

### [Patent Document]

[Patent Document 1] International Publication WO 2015/118901
[Patent Document 2] International Publication WO 2018/092722
[Patent Document 3] International Publication WO 2017/026247
[Patent Document 4] International Publication WO 2017/014020

### DISCLOSURE OF THE INVENTION

### Problem to be Solved by the Invention

However, the thin film capacitor described in Patent Document 1 has a side surface electrode structure, so that the line length of the electrode is long, which causes a structural problem of increasing an ESR (Equivalent Series Resistance) and an ESL (Equivalent Series Inductance). In addition, the thin film capacitor described in Patent Document 1 uses a metal substrate which is made entirely porous, so that it is not easy to separate a lower electrode constituted by the metal substrate and the upper electrode covering the metal substrate through the dielectric film, which disadvantageously makes it likely to cause a short circuit failure. In the thin film capacitor described in Patent Document 2, one main surface of the metal substrate functions as the upper electrode, and the other surface thereof functions as a lower electrode, so that, in order to dispose a pair of terminal electrodes on the same plane, it is necessary to route the electrode through the side surface of an element, complicating the structure. In the thin film capacitors described in Patent Documents 3 and 4, a pair of terminal electrodes are disposed respectively on both surfaces of a metal substrate, and this hinders access to the terminal electrode pair from one side. In addition, the presence of the support increases the entire thickness.

The present disclosure describes an improved thin film capacitor and a manufacturing method therefor, and an electronic circuit board having such a thin film capacitor.

### Means for Solving the Problem

A thin film capacitor according to one aspect of the present disclosure includes a metal foil having a non-roughened center portion and a roughened surface, a dielectric film covering the roughened surface of the metal foil, a first electrode layer contacting the metal foil, a second electrode layer contacting the dielectric film without contacting the metal foil, and an insulating member positioned between the first and second electrode layers, wherein the metal foil has a groove formed so as to penetrate a roughened surface layer of the metal foil and exposing therethrough the non-roughened center portion, and the insulating member contacts the center portion of the metal foil that is exposed to a bottom of the groove.

An electronic circuit board according to one aspect of the present disclosure includes a substrate having a wiring pattern, and a semiconductor IC and the thin film capacitor each provided in the substrate, wherein the first and second electrode layers of the thin film capacitor are connected to the semiconductor IC through the wiring pattern.

### Advantageous Effect of the Invention

According to the present disclosure, the groove penetrating the roughened surface layer of the metal foil is formed in the metal foil, allowing a pair of terminal electrodes to be disposed on the same plane without using a side surface electrode. In addition, the insulating member contacts the center portion of the metal foil that is exposed to the bottom of the groove, making peeling unlikely to occur in the insulating member.

### BRIEF DESCRIPTION OF THE DRAWINGS

FIG. 1A is a schematic cross-sectional view for explaining the structure of a thin film capacitor 1 according to a first embodiment of the present disclosure. FIG. 1B is a schematic plan view of the thin film capacitor 1.

FIGS. 1C and 1D are schematic views for explaining the definitions of the angles θ1 to θ3.

FIGS. 2A to 22A are schematic cross-sectional views for explaining a manufacturing process of the thin film capacitor 1 and taken along the line A-A in FIGS. 2B to 22B.

FIG. 23 is a schematic cross-sectional view for explaining the structure of a thin film capacitor 2 according to a second embodiment of the present disclosure.

FIG. 24 is a schematic cross-sectional view for explaining the structure of a thin film capacitor 3 according to a third embodiment of the present disclosure.

FIG. 25 is a schematic cross-sectional view showing an electronic circuit board having a configuration in which any one of the thin film capacitors 1 to 3 is embedded in a multilayer substrate 400.

FIG. 26 is a schematic cross-sectional view showing an electronic circuit board having a configuration in which any one of the thin film capacitors 1 to 3 is mounted on a multilayer substrate 600.

### MODE FOR CARRYING OUT THE INVENTION

Hereinafter, some embodiments of the present disclosure will be described in detail with reference to the accompanying drawings.

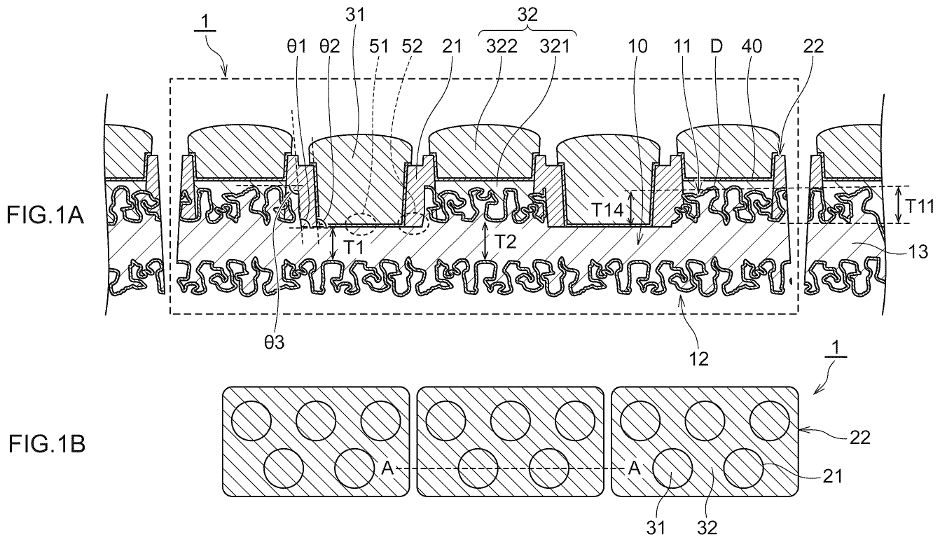

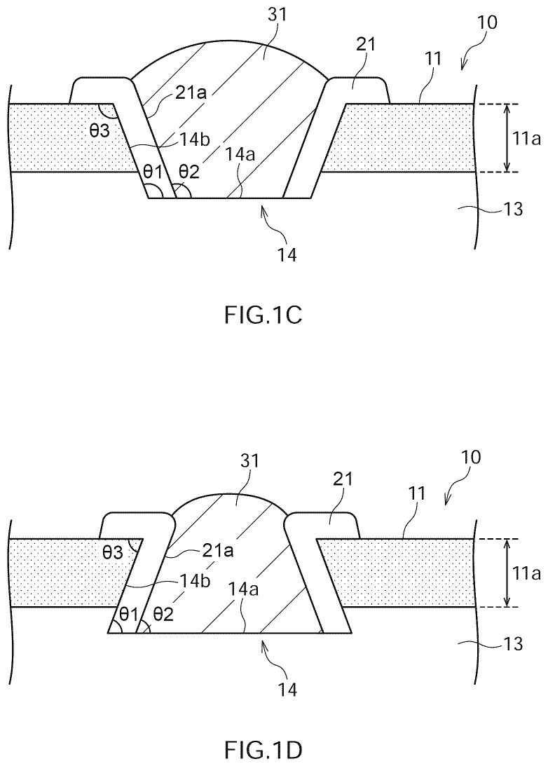

FIG. 1A is a schematic cross-sectional view for explaining the structure of a thin film capacitor 1 according to a first embodiment of the present disclosure. FIG. 1B is a schematic plan view of the thin film capacitor 1. FIG. 1A illustrates a cross section taken along the line A-A in FIG. 1B.

As illustrated in FIGS. 1A and 1B, the thin film capacitor 1 includes a metal foil 10 made of aluminum or the like, ring-shaped or polygonal annular insulating members 21 and 22 formed on an upper surface 11 of the metal foil 10, an electrode layer 31 formed on the upper surface 11 of the metal foil 10 and positioned in a region surrounded by the insulating member 21, and an electrode layer 32 formed on the upper surface 11 of the metal foil and positioned outside the region surrounded by the insulating member 21 but inside a region surrounded by the insulating member 22. The metal foil 10 may be made of copper, chrome, nickel, or tantalum in place of aluminum. The metal foil 10 has upper and lower main surfaces 11 and 12 positioned on the opposite sides. The upper surface 11 of the metal foil 10 is roughened excluding a region where the electrode layer 31 is provided. The lower surface 12 of the metal foil 10 is substantially entirely roughened. A center portion 13 of the metal foil 10 positioned between the upper and lower surfaces 11 and 12 is not roughened. A dielectric film D is formed on the roughened surface of the metal foil 10. When the metal foil 10 is made of aluminum, the dielectric film D may be made of aluminum oxide. The thickness of the non-roughened center portion 13 of the metal foil 10 is T1 in the region where the electrode layer 31 is provided and is T2 in other regions. The thickness T1 is smaller than the thickness T2.

The insulating members 21 and 22 are made of, e.g., a resin material. The electrode layer 31 is made of, e.g., a metal material such as copper, nickel, gold, or an alloy material thereof. The electrode layer 31 may have a multilayer structure including a plurality of laminated metal or alloy material layers. The electrode layer 31 is connected to the non-roughened center portion 13 of the metal foil 10 that has the thickness T1. A seed layer 40 may be interposed between the electrode layer 31 and the metal foil 10. In this case, the seed layer 40 serves as a part of the electrode layer 31. The electrode layer 32 includes conductive members 321 and 322. The conductive member 321 is made of, e.g., a conductive polymer material. The conductive member 322 is made of the same metal material as the electrode layer 31. The seed layer 40 may be interposed also between the conductive members 321 and 322. In this case, the seed layer 40 serves as a part of the electrode layer 32. The seed layer 40 may be made of a material having a barrier function capable of preventing diffusion of copper or the like constituting the electrode layer 31 and conductive member 322, having high adhesion to the metal foil 10 made of aluminum or the like, insulating members 21 and 22, and the conductive member 321 made of a conductive polymer or the like, and causing no damage on the conductive member 321.

The ring-shaped or polygonal annular insulating member 21 is provided in a slit that electrically separates the electrode layers 31 and 32. In the region surrounded by the insulating member 21, i.e., a region corresponding to the non-roughened center portion 13 of the metal foil that has the thickness T1, the dielectric film D formed on the upper surface 11 of the metal foil 10 is partially or entirely removed and thus has an opening, whereby the electrode layer 31 is electrically connected to the metal foil 10 through the seed layer 40. On the other hand, outside the region surrounded by the insulating member 21, the dielectric film D formed on the upper surface 11 of the metal foil 10 is not removed. That is, the electrode layer 32 contacts the dielectric film D without contacting the metal foil 10, and the electrode layer 32 and metal layer 10 are insulated from each other. This allows the electrode layers 31 and 32 to function as a pair of capacitive electrodes facing each other through the dielectric film D. The dielectric film D is formed on the roughened upper surface 11 of the metal foil 10, and the upper surface 11 has an increased surface area, whereby a large capacitance can be obtained.

The metal foil 10 has a groove 14 formed at a part thereof connected with the electrode layer 31. A depth T14 of the groove 14 is larger than a thickness T11 of the roughened surface layer of the metal foil 10. Accordingly, the groove 14 penetrates the roughened surface layer of the metal foil 10, and the non-roughened center portion 13 of the metal foil 10 is exposed to the bottom of the groove 14. The center portion 13 of the metal foil 10 exposed to the bottom of the groove 14 has a flat surface. The bottom of the groove 14 contacts the seed layer 40 and insulating member 21. The bottom of the groove 14 is flat, so that a void hardly occurs between the metal foil 10 and the seed layer 40 and between the metal foil 10 and the insulating member 21. This enhances adhesion of the electrode layer 31 and insulating member 21 to the metal foil 10.

The reference numeral 51 in FIG. 1A indicates a portion at which the flat center portion 13 of the metal foil 10 exposed to the bottom of the groove 14 contacts the seed layer 40. The reference numeral 52 in FIG. 1A indicates a portion at which the flat center portion 13 of the metal foil 10 exposed to the bottom of the groove 14 contacts the insulating member 21. The insulating member 21 is provided along the inner wall of the groove 14 so as to surround the electrode layer 31. When the bottom of the groove 14 is flat, a void hardly occurs between the metal foil 10 and the seed layer 40 and between the metal foil 10 and the insulating member 21. This enhances adhesion at the interfaces denoted by reference numerals 51 and 52. The angle θ1 formed by the bottom surface of the groove 14 and the inner wall of the groove 14 is preferably 90° or more. The angle θ2 formed by the bottom surface of the groove 14 and the inner wall of the insulating member 21 contacting the electrode layer 31 is preferably 90° or more. The angle θ3 formed by the upper surface 11 of the metal foil 10 that is positioned outside the groove 14 and the inner wall of the groove 14 is preferably 90° or more.

FIG. 1C is a schematic view for explaining in more detail the definitions of the angles θ1 to θ3. As illustrated in FIG. 1C, the angle θ1 is defined by the angle formed by the center portion 13 of the metal foil 10 that is exposed to a bottom 14a of the groove 14 and the lower-part surface, which is positioned at the lower portion of the groove 14, of the porous layer 11a constituting the surface layer of the metal foil 10 that is exposed to the inner wall 14b of the groove 14. The angle θ2 is defined by the angle formed by the center portion 13 of the metal foil 10 that is exposed to the bottom 14a of the groove 14 and an inner wall 21a of the insulating member 21 that contacts the electrode layer 31. The angle θ3 is defined by the angle formed by the upper surface 11 of the metal foil 10 that is positioned outside the groove 14 and upper-part surface, which is positioned at the upper portion of the groove 14, of the porous layer 11a constituting the surface layer of the metal foil 10 that is exposed to the inner wall 14b of the groove 14. In the example illustrated in FIG. 1D, the angles θ1 to θ3 are all equal to or less than 90°. When the angles θ1 to θ3 are 90° or less, interfacial peeling and void generation hardly occur. On the other hand, when the angles θ1 to θ3 are all exceed 90° as illustrated in FIG. 1C, interfacial peeling and void generation are likely to occur.

The thin film capacitor 1 can be used as a decoupling capacitor when being embedded in a multilayer substrate. Further, the electrode layer 31 is divided into a plurality of parts, so that ESR and ESL can be reduced as compared with when the number of the electrode layers 31 is one. Further, the thin film capacitor 1 has the groove 14 penetrating the porous layer 11a as the surface layer of the metal foil 10, and the electrode layer r 31 and insulating member 21 contact the flat bottom surface of the groove 14, thus enhancing adhesion of the electrode layer 31 and insulating member 21 to the metal foil 10. This makes peeling and void generation unlikely to occur.

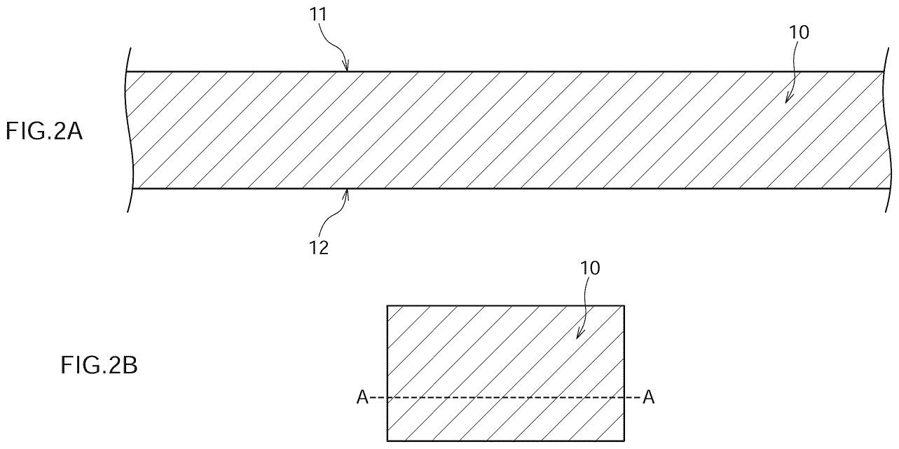

The following describes an example of a manufacturing method for the thin film capacitor 1. FIGS. 2A to 22A are schematic cross-sectional views taken along the line A-A in FIGS. 2B to 22B.

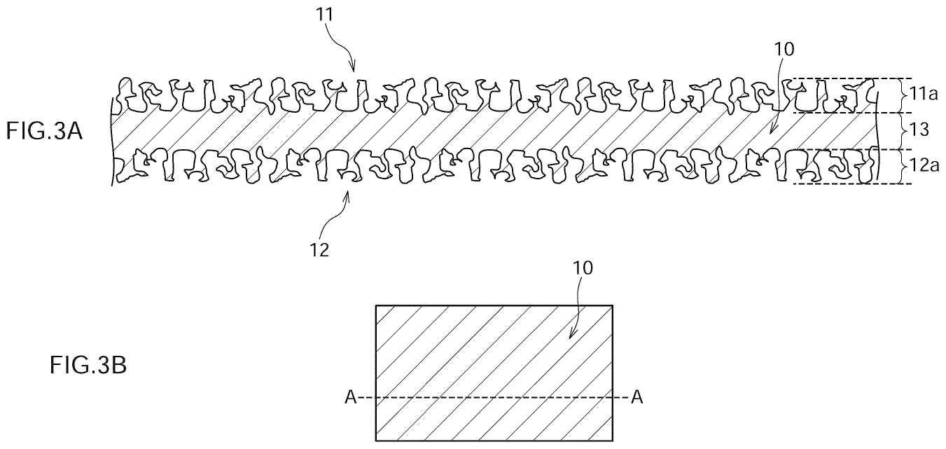

First, the metal foil 10 with a thickness of about 50 μm is prepared (FIGS. 2A and 2B), and the upper and lower surfaces 11 and 12 of the metal foil 10 are roughened by etching (FIGS. 3A and 3B). The center portion 13 of the metal foil 10 is not roughened. As a result, the metal foil 10 has a porous layer 11a positioned on the upper surface 11 side and a porous layer 12a positioned on the lower surface 12 side. The non-roughened center portion 13 is left between the porous layers 11a and 12a. Here, it is sufficient to roughen at least the upper surface 11, and the lower surface 12 need not necessarily be roughened; however, roughening both the upper and lower surfaces 11 and 12 can prevent warpage of the metal foil 10. Further, in place of roughening, metal powder may be sintered to form the metal foil 10 having roughened upper and lower surfaces 11 and 12.

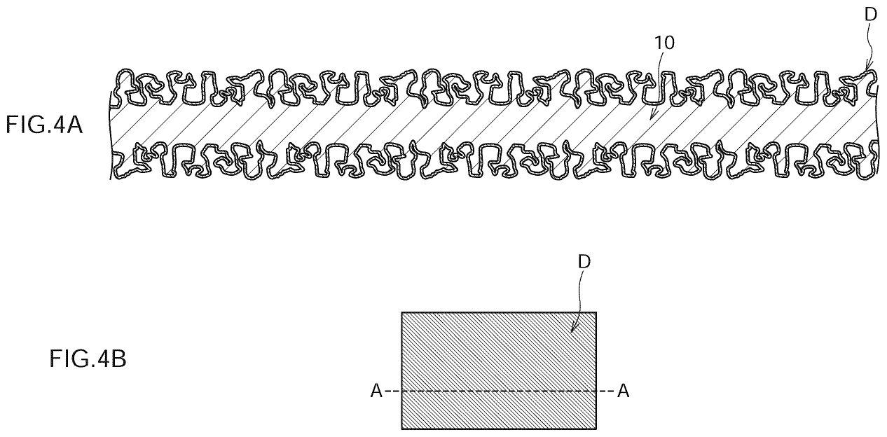

Then, the dielectric film D is formed on the surfaces of the metal foil 10 (FIGS. 4A and 4B). The dielectric film D may be formed through oxidation of the metal foil or using a film formation method excellent in coverage performance, such as an ALD method, a CVD method, or a mist CVD method. Examples of the material of the dielectric film D include Al₂O₃, TiO₂, Ta₂O₅, and SiNx. Here, the dielectric film D need not necessarily be formed on the lower surface 12 so long as it is formed at least on the upper surface 11; however, forming the dielectric film D on the lower surface 12 can provide sufficient insulation performance to the lower surface 12.

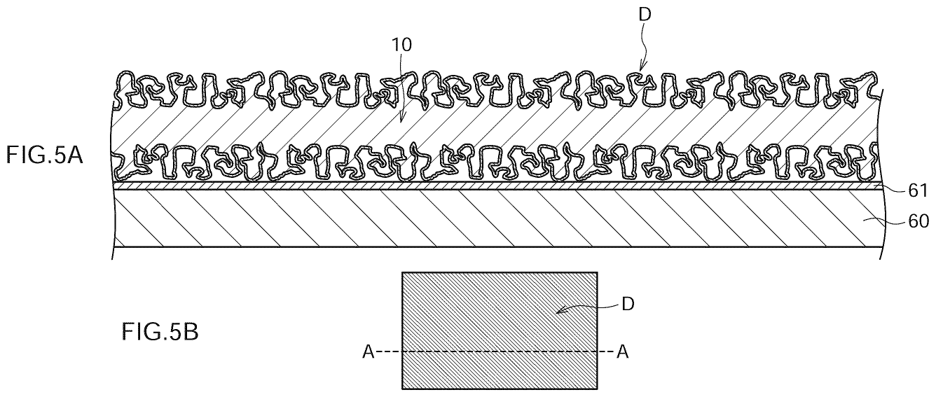

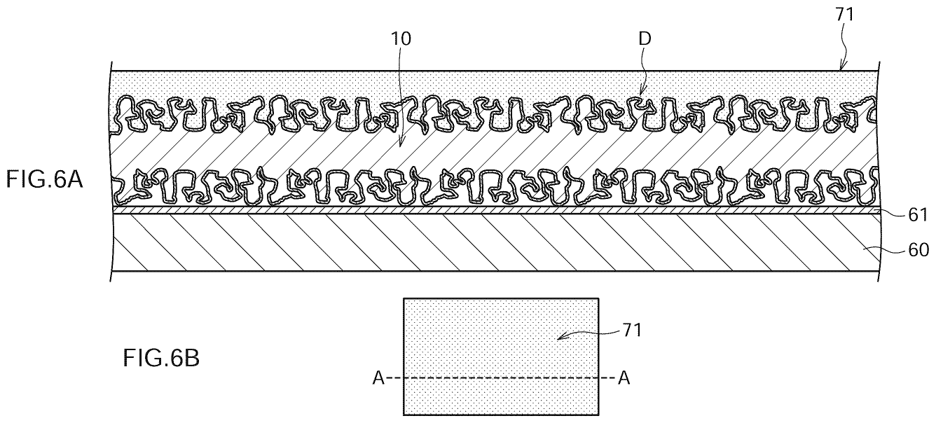

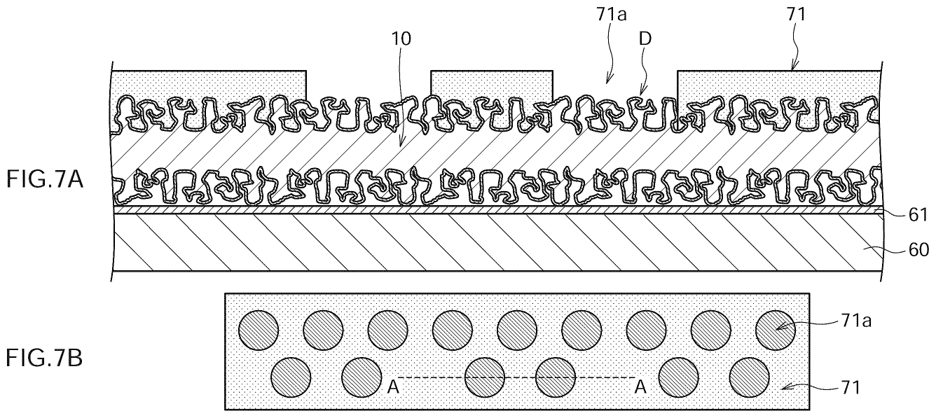

Then, the metal foil 10 is placed on a support substrate 60 with an adhesive layer 61 interposed therebetween (FIGS. 5A and 5B), a photosensitive liquid resist 71 is applied onto the upper surface 11 of the metal foil 10 positioned opposite the support substrate 60 (FIGS. 6A and 6B), followed by exposure and development to pattern the resist 71 (FIGS. 7A and 7B). The patterned resist 71 has a plurality of openings 71a exposing the dielectric film D. The resist may be a positive or negative resist.

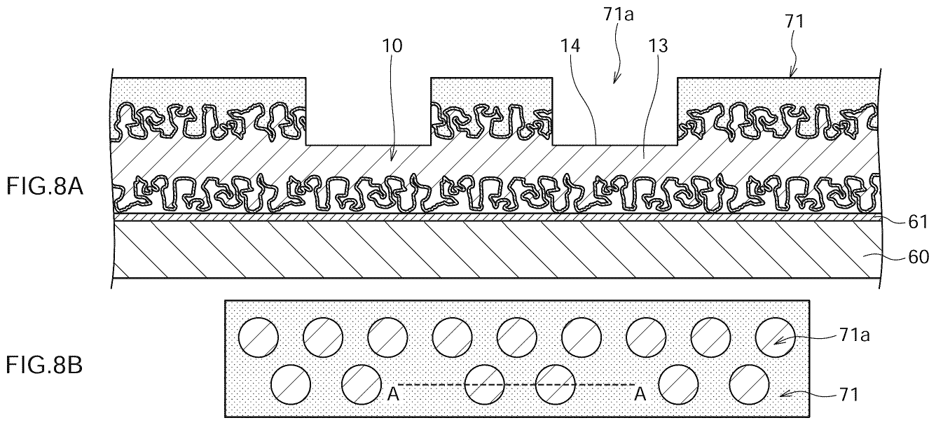

Then, the dielectric film D and metal foil 10 are etched using the resist 71 as a mask to form the groove 14 in the metal foil 10 at a position overlapping each of the openings 71a (FIGS. 8A and 8B). As a result, the dielectric film D has openings, through which the non-roughened center portion 13 of the metal foil 10 is exposed at the bottom of the groove 14.

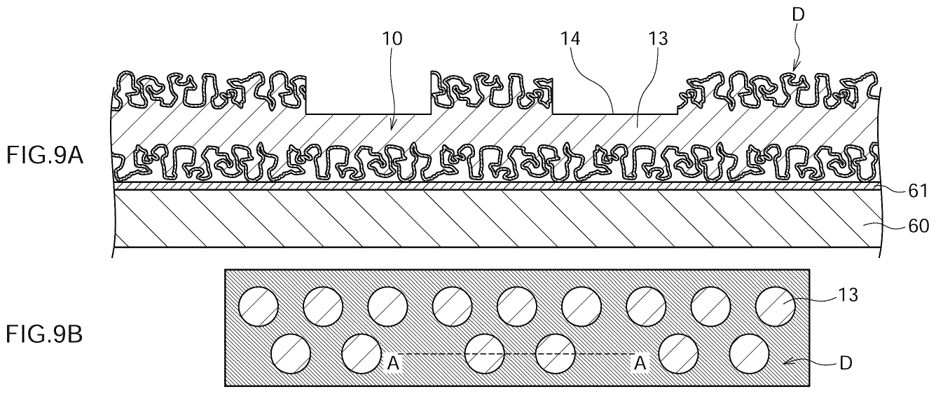

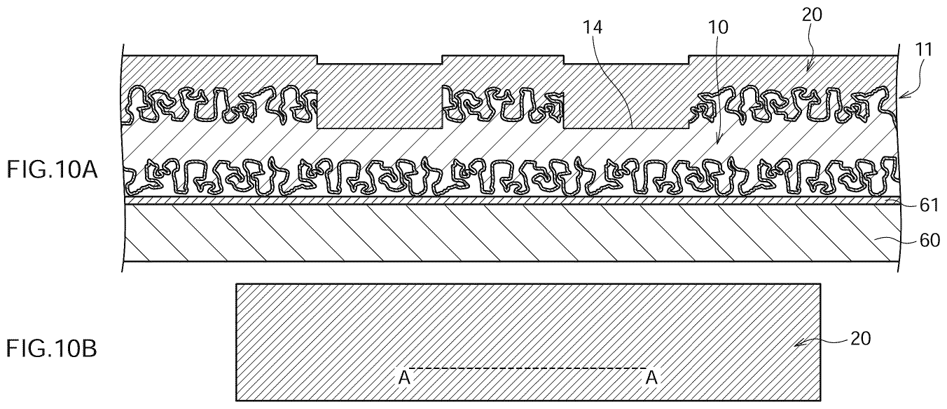

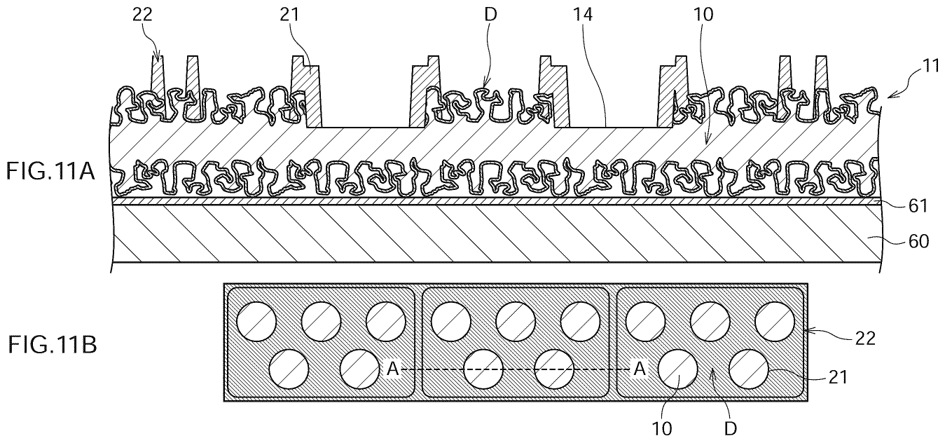

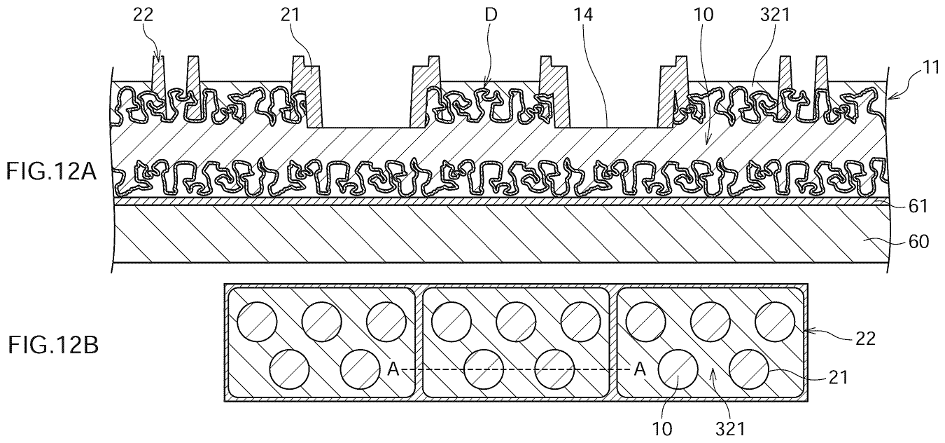

Then, after removal of the resist 71 (FIGS. 9A and 9B), a photosensitive insulating resin 20 is formed on the upper surface 11 of the metal foil 10 (FIGS. 10A and 10B). Subsequently, the insulating resin 20 is subjected to exposure and development to pattern the insulating resin (FIGS. 11A and 11B). As a result, the ring-shaped insulating members 21 and 22 are formed. The inner peripheral wall of the ring-shaped insulating member 21 may be positioned inside the groove 14 formed in the metal foil 10. The outer peripheral wall of the ring-shaped insulating member 21 needs to be positioned outside the groove 14 formed in the metal foil 10. Subsequently, the conductive member 321 made of a conductive polymer is formed outside the region surrounded by the insulating member 21 but inside the region surrounded by the insulating member 22 (FIGS. 12A and 12B). The conductive member 321 made of a conductive polymer is not formed in the region surrounded by the insulating member 21 and a portion where the metal foil 10 is to be removed for singulation (for example, a portion outside the region surrounded by the insulating member 22).

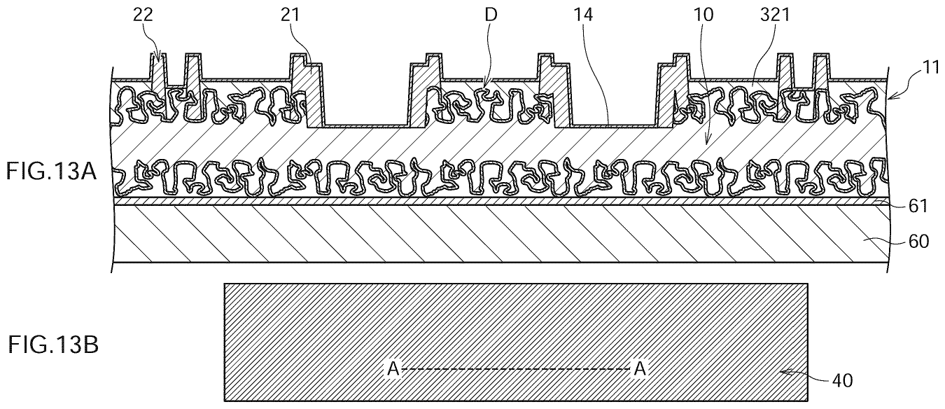

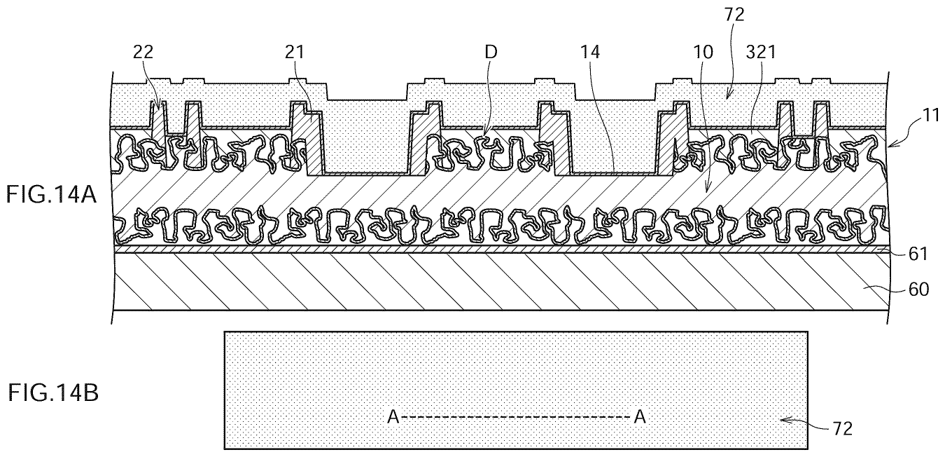

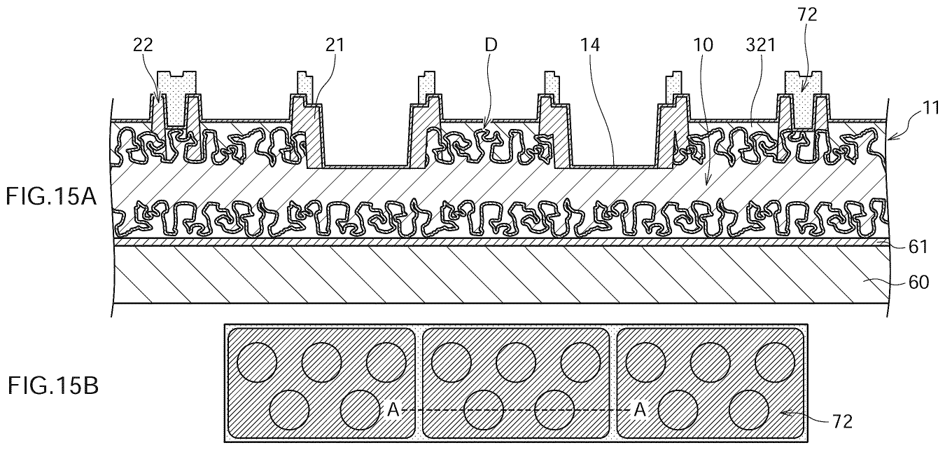

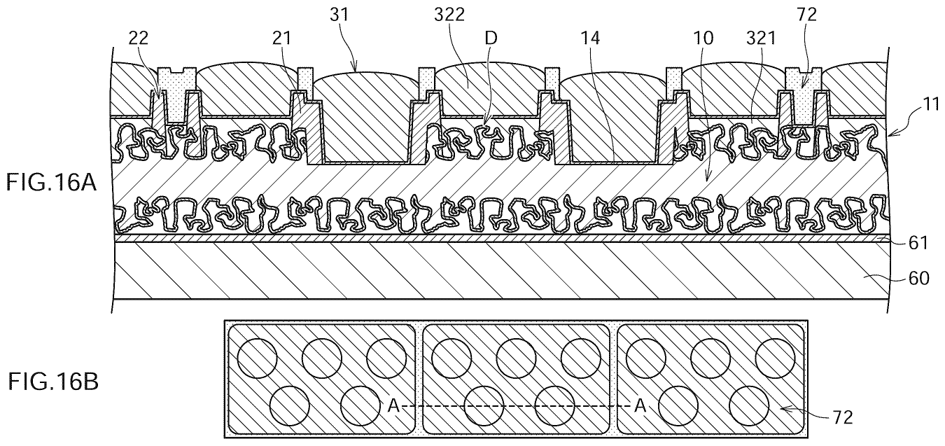

Then, the seed layer 40 is formed on the entire surface using a sputtering method or the like (FIGS. 13A and 13B). Before the seed layer 40 is formed, a residue remaining on the surface may be removed by reverse sputtering. Subsequently, a photosensitive liquid resist 72 is applied onto the entire surface (FIGS. 14A and 14B), followed by exposure and development to pattern the resist 72 (FIGS. 15A and 15B). As a result, the seed layer 40 in the singulation is region exposed. Subsequently, electrolytic plating is performed using the seed layer 40 as a feeding film to form the electrode layer 31 and the conductive member 322 of the electrode layer 32 (FIGS. 16A and 16B). As a result, the electrode layer 31 is connected to the metal foil 10, and the conductive member 322 is connected to the conductive member 321 made of a conductive polymer or the like.

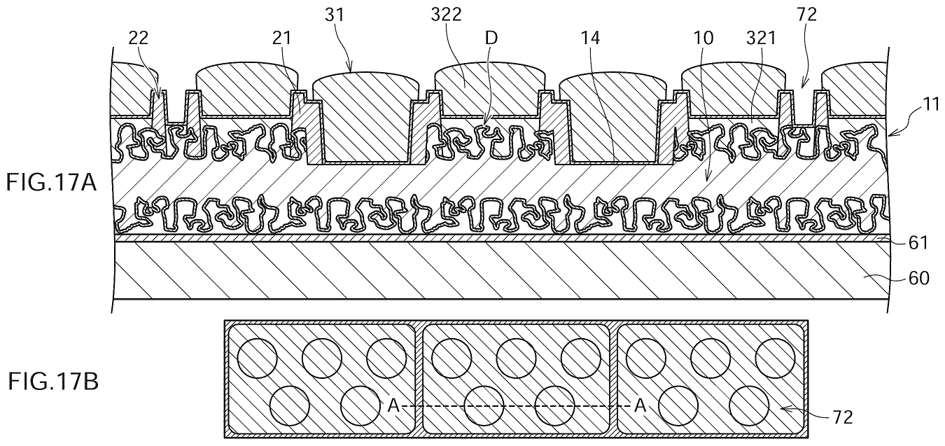

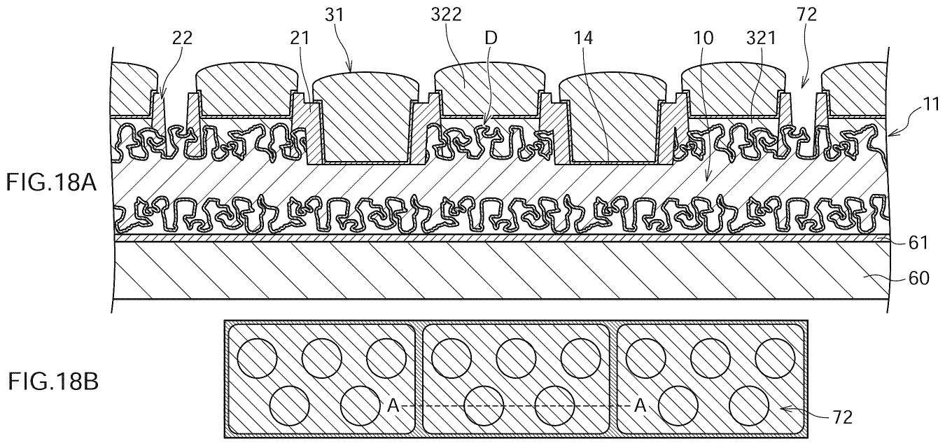

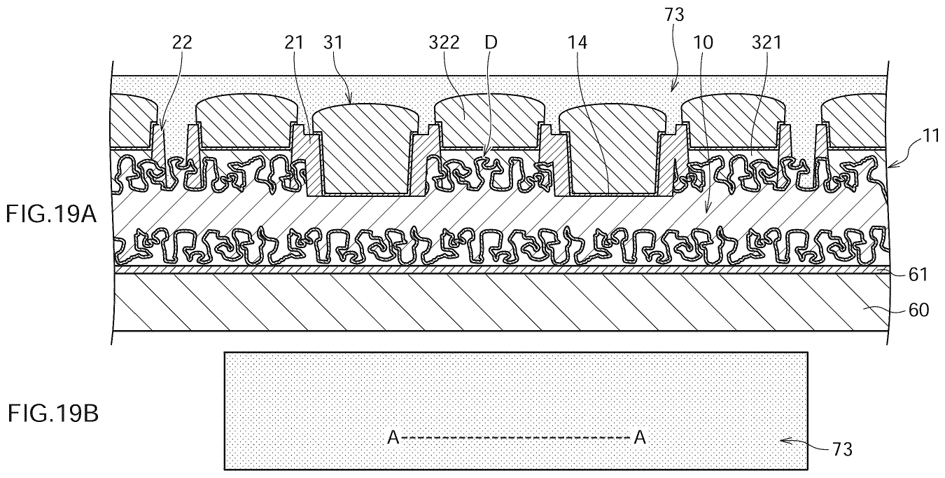

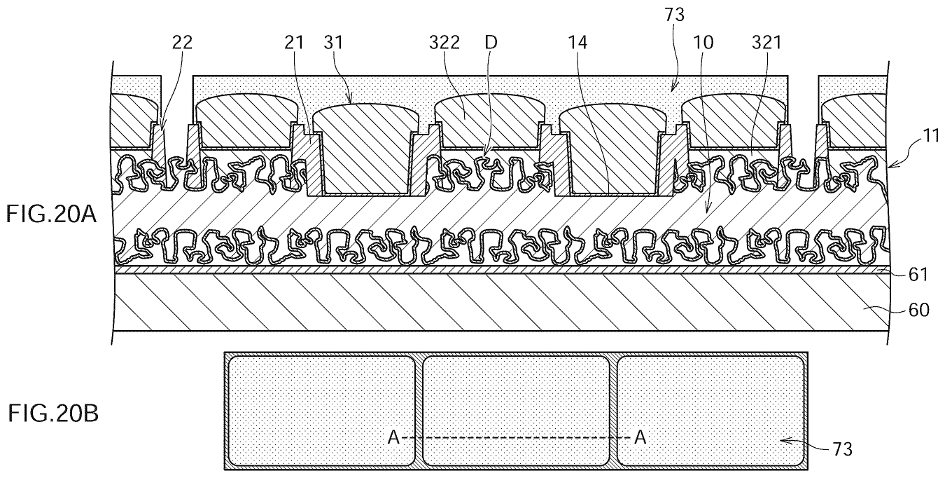

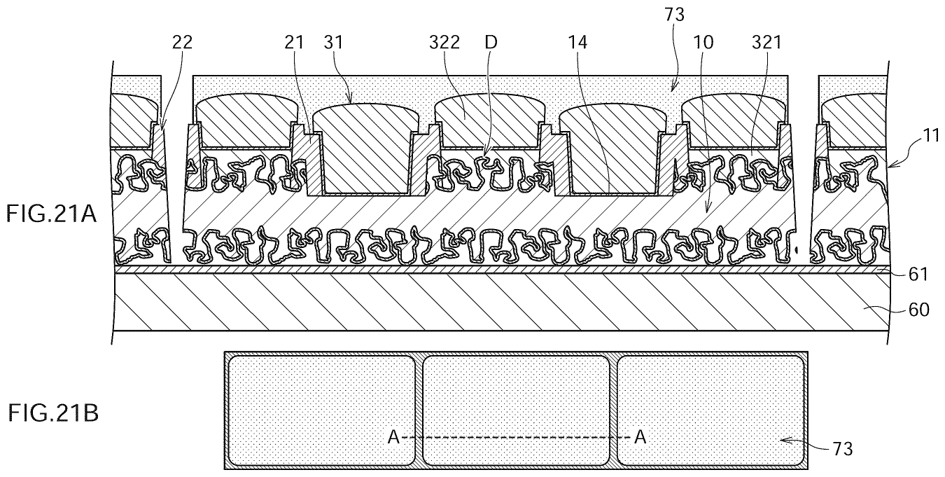

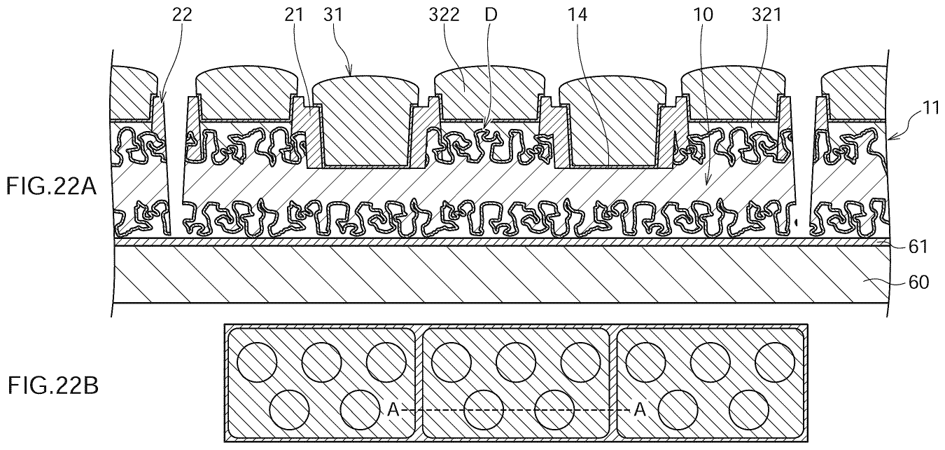

Then, after removing the resist 72 by ashing or the like (FIGS. 17A and 17B), an unnecessary part of the seed layer is removed (FIGS. 18A and 18B). Then, a photosensitive liquid resist 73 is applied onto the entire surface (FIGS. 19A and 19B), followed by exposure and development to pattern the resist 73 (FIGS. 20A and 20B). Subsequently, the metal foil 10 is etched using the resist 73 as a mask to singulate the thin film capacitor (FIGS. 21A and 21B). Subsequently, after removing the resist 73 by ashing or the like (FIGS. 22A and 22B), the support substrate 60 and adhesive layer 61 are removed, whereby the thin film capacitor 1 illustrated in FIGS. 1A and 1B is completed.

As described above, in the present embodiment, the center portion 13 of the metal foil 10 is exposed by formation of the groove 14 in the metal foil 10, so that adhesion of the electrode layer 31 and insulating member 21 to the metal foil 10 can be enhanced.

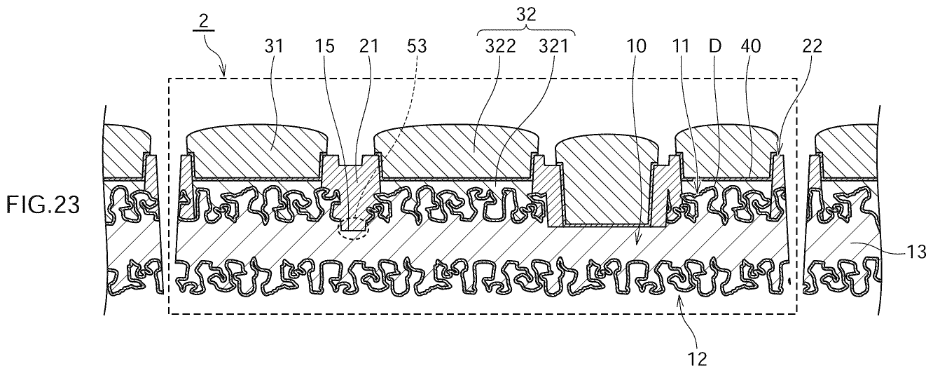

FIG. 23 is a schematic cross-sectional view for explaining the structure of a thin film capacitor 2 according to a second embodiment of the present disclosure.

As illustrated in FIG. 23, in the thin film capacitor 2, a groove 15 is additionally formed in the metal foil 10. The groove 15 is formed at a position where the electrode layer 31 is absent and is entirely filled with the insulating member 21. The groove 15 penetrates the roughened surface layer of the metal foil 10, and the non-roughened center portion 13 of the metal foil 10 is exposed to the bottom of the groove 15. Accordingly, the insulating member 21 filled in the groove 15 contacts the center portion 13 of the metal foil 10 that is exposed to the bottom of the groove 15. The reference numeral 53 in FIG. 23 indicates a portion where the flat center portion 13 of the metal foil 10 exposed to the bottom of the groove and the insulating member 21 contact each other. The insulating member 21 filled in the groove 15 may be integral with the insulating member 21 filled in the groove 14. In this case, the insulating member 21 filled in the groove 14 is reinforced by the insulating member 21 filled in the groove 15, making peeling less likely to occur.

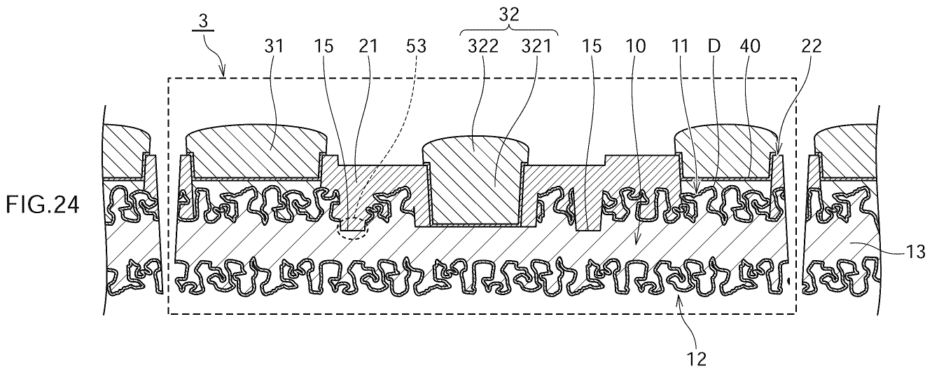

FIG. 24 is a schematic cross-sectional view for explaining the structure of a thin film capacitor 3 according to a third embodiment of the present disclosure.

As illustrated in FIG. 24, in the thin film capacitor 3, the groove 15 has a ring shape and surrounds the groove 14 in which the electrode layer 31 is provided. The insulating member 21 filled in the groove 15 is integral with the insulating member 21 filled in the groove 14. Thus, the insulating member 21 filled in the groove 14 is reinforced by the insulating member 21 filled in the ring-shaped groove 15, making peeling less likely to occur.

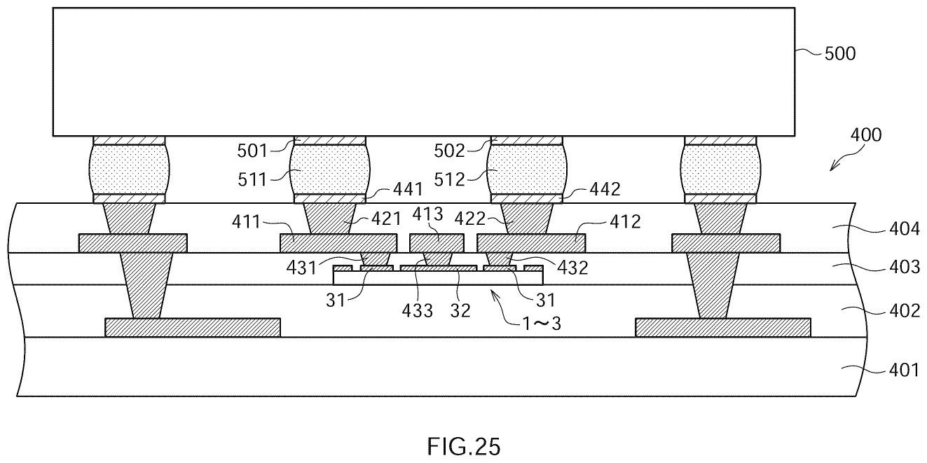

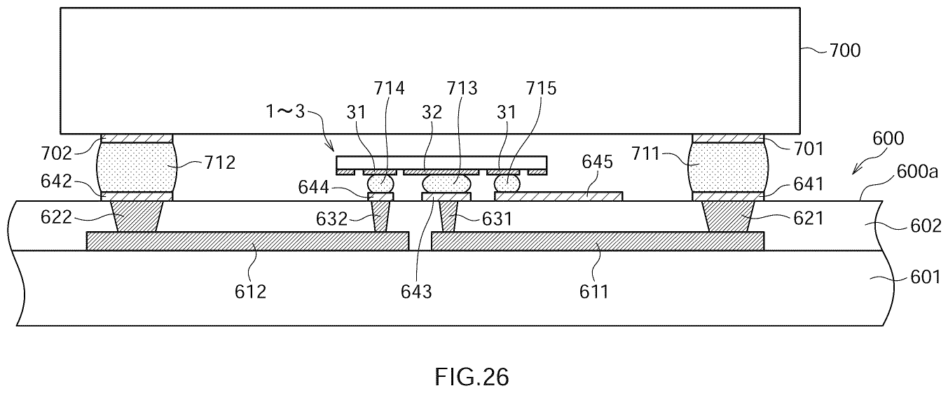

The above-described thin film capacitors 1 to 3 may be embedded in a multilayer substrate 400 as illustrated in FIG. 25 or mounted on the surface of a multilayer substrate 600 as illustrated in FIG. 26.

An electronic circuit board illustrated in FIG. 25 has a configuration in which a semiconductor IC 500 is mounted on a multilayer substrate 400. The multilayer substrate 400 includes a plurality of insulating layers including insulating layers 401 to 404 and a plurality of wiring patterns including wiring patterns 411 and 413. The number of the insulating layers is not particularly limited. In the example illustrated in FIG. 25, any one of the thin film capacitors 1 to 3 is embedded between the insulating layers 402 and 403. There are provided on the surface of the multilayer substrate 400 a plurality of land patterns including land patterns 441 and 442. The semiconductor IC 500 has a plurality of pad electrodes including pad electrodes 501 and 502. For example, the pad electrodes 501 and 502 are power supply terminals. The pad electrode 501 and land pattern 441 are connected to each other through a solder 511, and the pad electrode 502 and land pattern 442 are connected to each other through a solder 512. The land pattern 441 is connected to the electrode layer 31 of the thin film capacitor (1 to 3) through a via conductor 421, the wiring pattern 411, and a via conductor 431. The land pattern 442 is connected to another electrode layer 31 of the thin film capacitor (1 to 3) through a via conductor 422, the wiring pattern 412, and a via conductor 432. The electrode layer 32 of the thin film capacitor (1 to 3) is connected to another pad electrode provided on the semiconductor IC 500 through a via conductor 433 and the wiring pattern 413. The above-mentioned another pad electrode is a ground terminal, for example. With this configuration, the thin film capacitors 1 to 3 each function as a decoupling capacitor for the semiconductor IC 500.

An electronic circuit board illustrated in FIG. 26 has a configuration in which a semiconductor IC 700 is mounted on a multilayer substrate 600. The multilayer substrate 600 includes a plurality of insulating layers including insulating layers 601 and 602 and a plurality of wiring patterns including wiring patterns 611 and 612. The number of the insulating layers is not particularly limited. In the example illustrated in FIG. 26, any one of the thin film capacitors 1 to 3 is surface-mounted on a surface 600a of the multilayer substrate 600. There are provided on the surface 600a of the multilayer substrate 600 a plurality of land patterns including land patterns 641 to 645. The semiconductor IC 700 has a plurality of pad electrodes including pad electrodes 701 and 702. For example, one of the pad electrodes 701 and 702 is a power supply terminal, and the other one thereof is a ground terminal. The pad electrode 701 and land pattern 641 are connected to each other through a solder 711, and the pad electrode 702 and land pattern 642 are connected to each other through a solder 712. The land pattern 641 is connected to the electrode layer 32 of the thin film capacitor (1 to 3) through a via conductor 621, the wiring pattern 611, a via conductor 631, the land pattern 643, and a solder 713. The land pattern 642 is connected to the electrode layer 31 of the thin film capacitor (1 to 3) through a via conductor 622, the wiring pattern 612, a via conductor 632, the land pattern 644, and a solder 714. The land pattern 645 is connected to another electrode layer 31 through a solder 715. With this configuration, the thin film capacitors 1 to 3 each function as a decoupling capacitor for the semiconductor IC 700.

While the preferred embodiment of the present disclosure has been described, the present disclosure is not limited to the above embodiment, and various modifications may be made within the scope of the present disclosure, and all such modifications are included in the present disclosure.

### REFERENCE SIGNS LIST

1-3 thin film capacitor
10 metal foil
11 upper surface of metal foil
12 lower surface of metal foil
11a, 12a porous layer
13 center portion
14, 15 groove
14a bottom of groove
14b inner wall of groove
21, 22 insulating member
21a inner wall of insulating member
30 metal film
31, 32 electrode layer
40 seed layer
51-53 interface
60 support substrate
61 adhesive layer
70-73 resist
71a opening of resist
321, 322 conductive member
400 multilayer substrate
401-404 insulating layer
411-413 wiring pattern
421, 422, 431-433 via conductor
441, 442 land pattern
500 semiconductor IC
501, 502 pad electrode
511, 512 solder
600 multilayer substrate
600a surface of multilayer substrate
601, 602 insulating layer
611, 612 wiring pattern
621, 622, 631, 632 via conductor
641-645 land pattern
700 semiconductor IC
701, 702 pad electrode
711-715 solder
D dielectric film

1. A thin film capacitor comprising:
a metal foil having a non-roughened center portion and a roughened surface;
a dielectric film covering the roughened surface of the metal foil;
a first electrode layer contacting the metal foil;
a second electrode layer contacting the dielectric film without contacting the metal foil; and
an insulating member positioned between the first and second electrode layers,
wherein the metal foil has a groove formed so as to penetrate a roughened surface layer of the metal foil and exposing therethrough the non-roughened center portion, and
wherein the insulating member contacts the center portion of the metal foil that is exposed to a bottom of the groove.

2. The thin film capacitor as claimed in claim 1,
wherein the first electrode layer contacts the center portion of the metal foil that is exposed to the bottom of the groove, and
wherein the insulating member is provided along an inner wall of the groove so as to surround the first electrode layer.

3. The thin film capacitor as claimed in claim 2, wherein an angle formed by the center portion of the metal foil that is exposed to the bottom of the groove and a lower-part surface, which is positioned at a lower portion of the groove, of the surface layer of the metal foil that is exposed to the inner wall of the groove is 90° or more.

4. The thin film capacitor as claimed in claim 3, wherein an angle formed by the surface of the metal foil that is positioned outside the groove and an upper-part surface, which is positioned at an upper portion of the groove, of the surface layer of the metal foil that is exposed to the inner wall of the groove is 90° or more.

5. The thin film capacitor as claimed in claim 2, wherein an angle formed by the center portion of the metal foil that is exposed to the bottom of the groove and an inner wall of the insulating member that contacts the first electrode layer is 90° or more.

6. The thin film capacitor as claimed in claim 1, wherein the second electrode layer includes a first conductive member contacting the dielectric film and made of a conductive polymer material and a second conductive member contacting the first conductive member and made of a metal material.

7. An electronic circuit board comprising:
a substrate having a wiring pattern; and
a semiconductor IC and the thin film capacitor as claimed in claim 1 each provided in the substrate,
wherein the first and second electrode layers of the thin film capacitor are connected to the semiconductor IC through the wiring pattern.
